(19) United States
(12) Patent Application Publication
(10) Pub. No.: US 2007/0227878 A1
(43) Pub. Date: Oct. 4, 2007

(54) Forming ovonic threshold switches with reduced deposition chamber gas pressure

(76) Inventors: Roger Hamamjy, San Jose, CA (US); Kuo-Wei Chang, Sunnyvale, CA (US); Jason S. Reid, San Jose, CA (US)

Correspondence Address: TROP PRUNER & HU, PC, 1616 S. VOSS ROAD, SUITE 750, HOUSTON, TX, 77057-2631, US

(21) Appl. No.: 11/392,135

(22) Filed: Mar. 29, 2006

(51) Int. Cl. C23C 14/00

(52) U.S. Cl. 204/192.12

(57) ABSTRACT

A phase change memory including an ovonic threshold switch may be formed with reduced argon in the ovonic threshold switch. The presence of argon adversely impacts the performance of the ovonic threshold switch. Argon concentration can be reduced by depositing the phase change material for the ovonic threshold switch in a relatively low pressure argon environment to enable the argon pressure within said chamber to be reduced.

### BACKGROUND

This invention relates generally to phase change memories.

Phase change memory devices use phase change materials, i.e., materials that may be electrically switched between a generally amorphous and a generally crystalline state, for electronic memory application. One type of memory element utilizes a phase change material that may be, in one application, electrically switched between a structural state of generally amorphous and generally crystalline local order or between different detectable states of local order across the entire spectrum between completely amorphous and completely crystalline states. The state of the phase change materials is also non-volatile in that, when set in either a crystalline, semi-crystalline, amorphous, or semi-amorphous state representing a resistance value, that value is retained until changed by another programming event, as that value represents a phase or physical state of the material (e.g., crystalline or amorphous). The state is unaffected by removing electrical power.

### BRIEF DESCRIPTION OF THE DRAWINGS

FIG. 1 is a depiction of a physical vapor deposition chamber in accordance with one embodiment of the present invention;

FIG. 2 is an enlarged depiction of a portion of the wafer clamp shown in FIG. 1 in accordance with one embodiment of the present invention;

FIG. 3 is a top plan view of a cluster tool in accordance with one embodiment of the present invention;

FIG. 4 is an enlarged, cross-section of a phase change memory at an early stage of manufacture according to one embodiment;

FIG. 5 is an enlarged, cross-section of a phase change memory at a subsequent stage of manufacture;

FIG. 6 is an enlarged, cross-sectional view of a phase change memory at a subsequent stage of manufacture according to one embodiment; and

FIG. 7 is a system depiction for one embodiment.

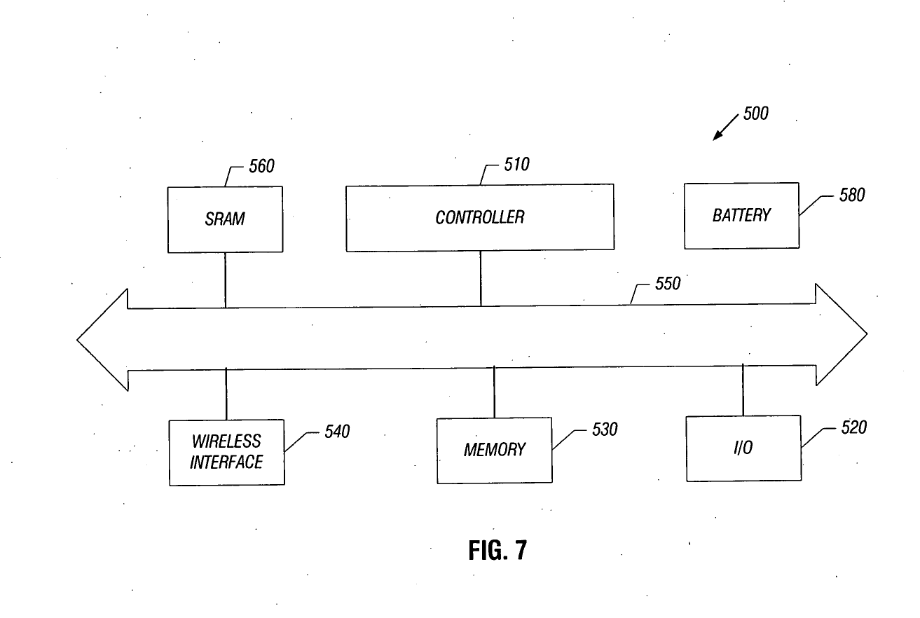

### DETAILED DESCRIPTION

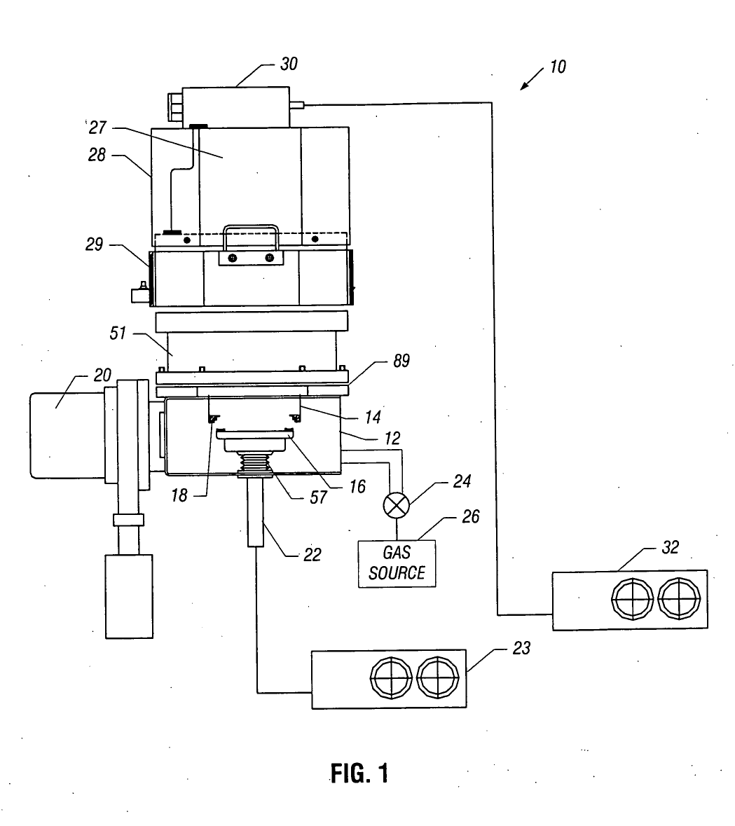

Referring to FIG. 1, a radio frequency (RF) and pulsed direct current (DC) physical vapor deposition (PVD) reactor 10 includes a vacuum chamber 12. In some embodiments, the vacuum chamber 12 may be grounded and may be formed of metal. A controller 22 controls the power supplies and the mass flow controller 24. The mass flow controller 24 is responsible for inletting a gas source 26 to the vacuum chamber 12. The gas source 26 may be a noble gas such as argon. In one embodiment, the chamber 12 may have shielding with twin wire arc spray.

Inside the chamber 12 is a grounded shield 14. The grounded shield 14 is coupled to a wafer clamp 18. The wafer clamp 18 clamps a wafer (not shown in FIG. 1) on to a pedestal electrode 16. The electrode 16 may be coupled to a bias potential controlled by the controller 22 in some embodiments. The pedestal electrode 16 may include an electrostatic chuck 57.

Finally, at the top of the chamber 12 is the target (not shown) which is made of the material to be sputtered on a wafer mounted on the pedestal electrode 16 by the clamps 18.

The vacuum within the chamber 12 may be established by cryopump 20 which communicates through a port (not shown) with the chamber 12. The cryopump 20 maintains a low pressure within the chamber 12. In one embodiment, it may be a two phase pump.

A DC magnetron and radio frequency generator 28 may include a lid cover 27 made of metal, such a aluminum, instead of plastic for better RF shielding to the source. Finally, a metal plate 89 may be located between the target 86 and the generator 28. The plate 89 may be formed of aluminum. The plate 89 may enable better source grounding.

Over the generator 28 may be situated a radio frequency matching circuit 30. The circuit 30 balances out the radio frequency energy from the generator to the chamber load. The RF matching circuit 30 enables the tuning of the RF power supply to the chamber 12. The matching circuit 30 is coupled to a radio frequency power supply 32. In one embodiment, the power supply is a 13.56 MHZ power supply. A radio frequency interference shield G-12 source 29 may be used.

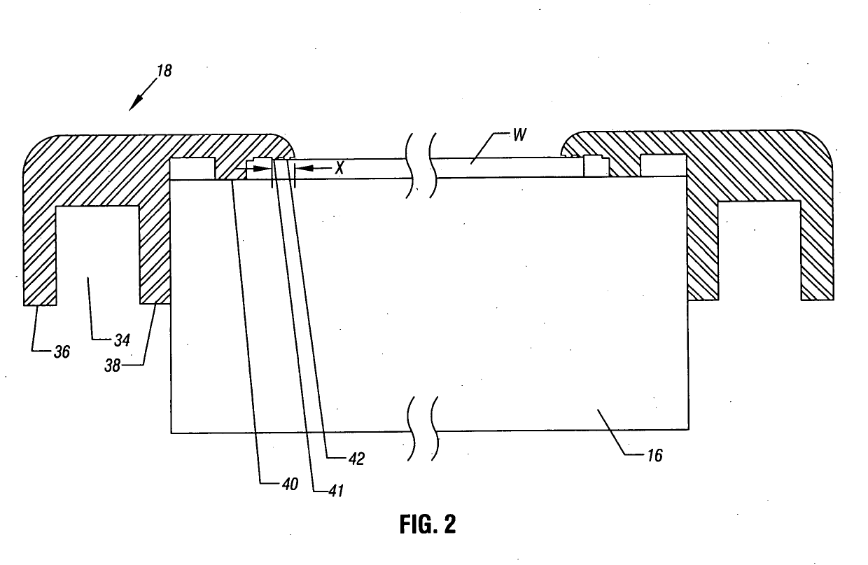

Referring to FIG. 2, the clamp ring 18 includes a pair of downwardly extending arms 38 and 36 which engage, between them the grounded shield 14. The ring 18 may be made of a ceramic material to isolate the electrostatic chuck 57 because radio frequency energy can travel through metal. An arm 40 extends transversely thereto and is useful for securing the wafer “W” in position on the pedestal electrode 16. The arm 40 includes a pair of spaced prongs 41 and 42. The outer prong 42 is spaced from the innermost edge 43 of the clamp ring 14 by a distance X.

The clamp ring 18 may have an edge exclusion, indicated by the distance X, of 6.5 millimeters in some embodiments of the present invention. Such an edge exclusion results in minimal contact with the edge of the wafer W. Also, an increased edge exclusion may protect more surface area to prevent cross contamination in the RF physical vapor deposition environment.

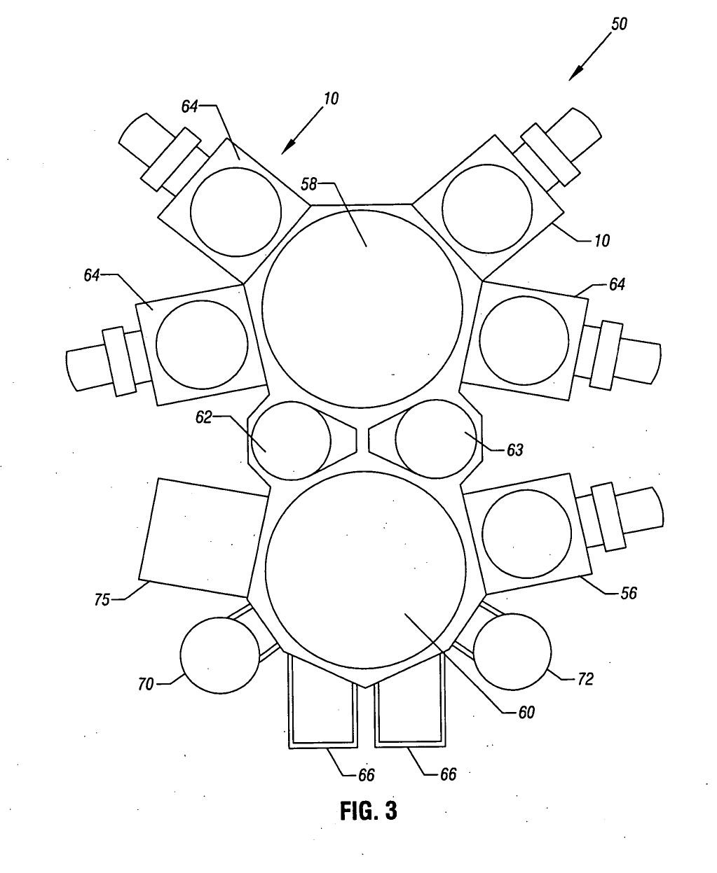

Referring to FIG. 3, a staged-vacuum wafer processing cluster tool 50 may include the reactor 10. A plurality of other chambers 64 may be situated around a transfer robot chamber 58 which includes a robot therein. The robot contained within the chamber 58 transfers wafers between each of the chambers 64 surrounding it and the chamber 10. The robot in the chamber 58 may receive wafers from the treatment chamber 62 and may pass wafers outwardly through the cool down treatment chamber 63. Each of the chambers 64 may be capable of processing the wafer in a different fabrication step. In some cases, each of the chambers may be able to implement one or more of the steps involved in physical vapor deposition.

The robot buffer chamber 60 also includes a robot. That robot may receive wafers from a load lock chamber 66, and transfer them to different stations surrounding the robot buffer chamber 60 or to the treatment chamber 62 for transfer to the transfer robot chamber 58. For example, the chamber 75 may be a pre-clean chamber and the chamber 56 may provide a barrier chemical vapor deposition chamber. The chambers 70 and 72 may be used for degassing and orientation.

Thus, the robot in the robot buffer chamber 60 grabs a wafer from a load lock chamber 66 and transports the wafer to chambers 70, 72 for degassing and orientation. From there the robot in the chamber 60 transfers the wafer to chamber 56 for chemical vapor deposition barrier layer formation in some embodiments of the present invention. Then, the wafer may be transferred to the pre-clean chamber 75.

Finally, the wafer may be transferred by the robot in the robot buffer chamber 60 to the treatment chamber 62 for transfer to the robot chamber 58. From there, various physical vapor deposition (or other steps) may be completed, including the RF or pulsed DC deposition of highly resistive layers in the chamber 10. Once the processing is done, the robot in the chamber 58 transfers the wafer to the cool down treatment chamber 63. From there, it can be accessed by the robot buffer chamber 60 robot and transferred out of the cluster tool 50 through a load lock chamber 66.

In some embodiments of the present invention, the reactor 10 may RF sputter deposit more highly resistive films, such as chalcogenide films. However, the same chamber may also be utilized for pulsed direct current sputtering as well. Because the RF power source is isolated from the rest of the components in the tool 50, RF interference with other chambers and with computer cluster tool 50 controllers that control the robots and other RF sensitive elements may be reduced.

In particular, better RF shielding for the source may be provided, RF power may be isolated from traveling on communication lines, and better source grounding may be achieved. As a result, in some embodiments of the present invention, RF sputtering may be implemented in a cluster tool despite the sensitivity of other components in the cluster tool to the radio frequency power.

A phase change memory may be formed utilizing the apparatus shown in FIG. 3. In one embodiment, a self-ionization plasma is established. A plasma that is self-ionizing may be established by using high pressure and high power to ignite the plasma. Then, the pressure and the power may be reduced, but the plasma maintains itself with a very low flow of argon gas from the gas source 26.

One advantage of such a system is that the amount of argon in the deposited layer is reduced. This is particularly important in connection with forming phase change memories with ovonic threshold switch (OTS) access devices. It has been determined that reducing the argon concentration within the chalcogenide used within the ovonic threshold switch improves the performance of the phase change memory.

Conventionally, a phase change memory may be formed with an access device such as an ovonic threshold switch. The ovonic threshold switch may use a chalcogenide material that generally does not change phase in operation. Thus, the ovonic threshold switch is used to access the phase change memory which also includes a chalcogenide layer.

The use of a self-ionization plasma enables lower argon flow to be used during the deposition of the chalcogenide layer used to form the ovonic threshold switch. This results in less contamination with the argon in the deposited layer.

In order to establish a self-ionization plasma, 2.0 MHZ power may be applied at the pedestal and 13.56 MHZ may be applied at the target. In another embodiment, 60 MHZ may be applied at the target and 13.56 MHZ may be applied at the pedestal.

In some embodiments of the present invention, the ovonic threshold switch chalcogenide layer may be deposited using a self-ionization plasma with chamber pressures below 3 milliTorr. In one advantageous embodiment, a chamber pressure of less than 1 milliTorr is used. Thus, the combination of a radio frequency or pulse energy deposition chamber, together with low argon pressures within the chamber, is effective to reduce the contamination by argon of chalcogenide containing layers used to form ovonic threshold switches.

To facilitate the application of the low pressure, an electrostatic chuck 57 may be utilized. Higher pressure may be used to ignite the plasma, but the pressure may be reduced and the electrostatic chuck 57 is effective to leak a relatively small flow of argon into the region of chamber 12 around the wafer.

Conventionally, reducing the argon pressure to such a low pressure to avoid contamination would result in the extinguishing of the plasma. However, a self-ionization plasma may be used at relatively low gas pressures.

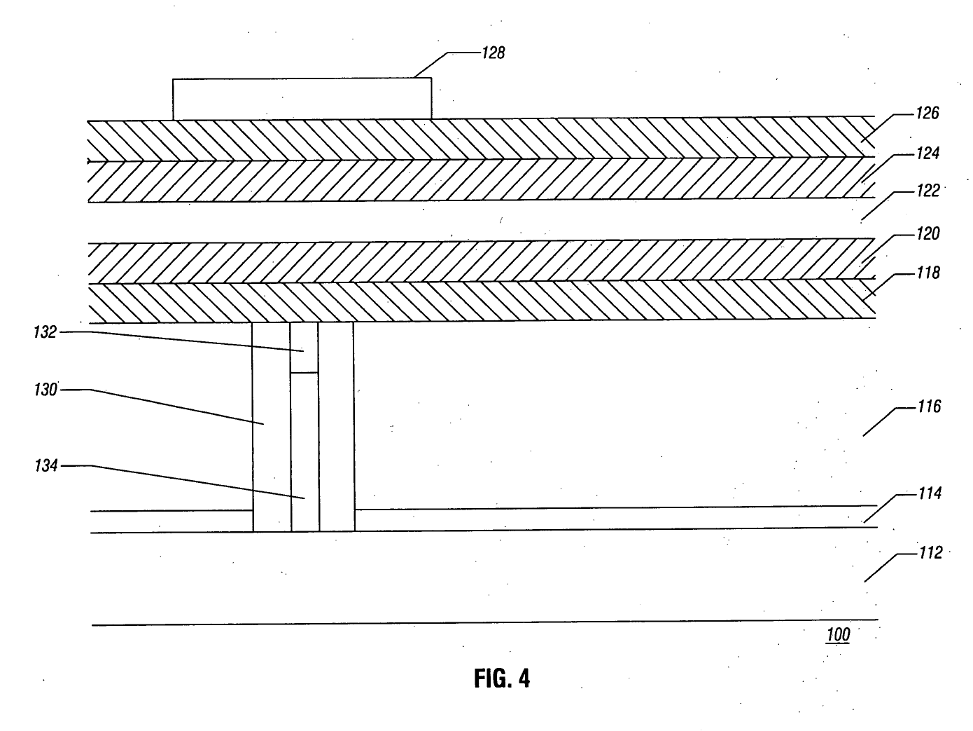

Referring to FIG. 4, a phase change memory may be formed of a stack including an ovonic unified memory (OUM) underlying a selection device in the form of an ovonic threshold switch. The ovonic unified memory may be formed on the substrate 100. Over the substrate 100 may be a row line conductor or electrode 112. While the conductor 112 is referred to as a row line, this is merely a convention and any electrode may be utilized.

A pair of insulating layers 114 and 116 may then be formed over the conductor 112. The insulating layer 114 may be thinner than the insulating layer 116 in one embodiment of the present invention. Then, a pore or via hole is formed through the layers 114 and 116. That via hole may then be filled with a lance oxide 130, a lance heater 134, and a phase change memory element 132. Thus, the structure shown in FIG. 4 may be called a damascene ovonic unified memory. The phase change material 132 may be a chalcogenide in one embodiment of the present invention.

Overlying the material 132 may be an electrode 118. The electrode 118 may be a common electrode acting as the upper electrode of the ovonic unified memory and the lower electrode of the overlying ovonic threshold switch. In one embodiment, the electrode 118 may be formed of titanium aluminum nitride or titanium and titanium nitride.

A pair of conductive layers 120 and 124 may be formed on either side of a chalcogenide layer 122. It is the layer 122 that is deposited using the equipment described in connection with FIGS. 1 and 2. The chalcogenide layer 122 does not change phase and is used to form the ovonic threshold switch. The conductive layers 120, 124 may be formed of carbon in one embodiment.

Over the upper layer 124 may be formed an upper electrode 126. The upper electrode 126 may be made of the same or different material as the lower electrode 118. Finally, a hard mask 128 may be deposited patterned over the structure.

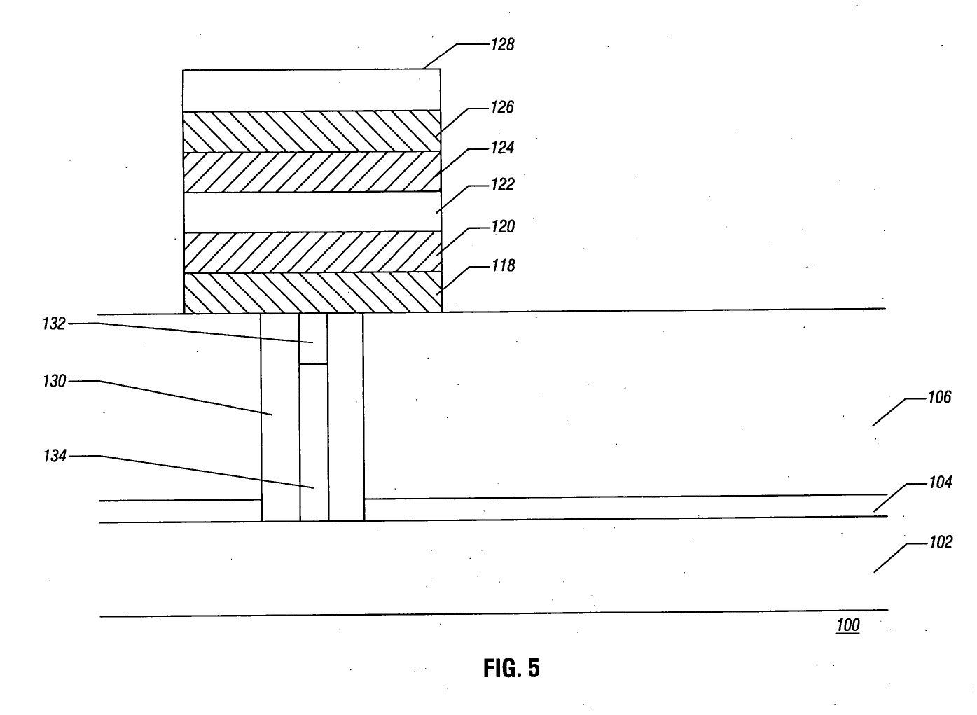

Referring to FIG. 5, the hard mask 128, in one embodiment, may be utilized to etch a dot or reduced length stack of layers that correspond to the patterned dimensions of the hard mask 128. The hard mask 128 may be any material which is suitably resistant to the etching material utilized to form the dot or stack shown in FIG. 5.

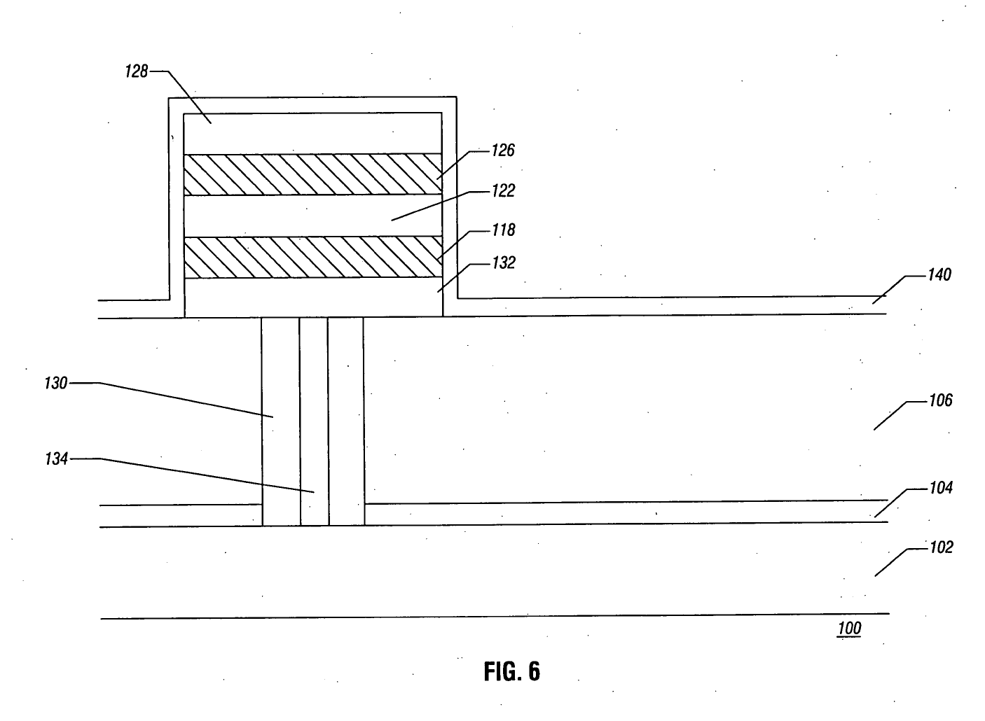

After completing the structure shown in FIG. 5, the entire structure may then be coated with a suitable passivation layer 140 as shown in FIG. 6. One such passivation layer 140 is a low temperature silicon nitride (Si3N4) encapsulation.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
forming a phase change memory element including chalcogenide using a self-ionization plasma.

2. The method of claim 1 including applying a potential to a pedestal and another potential to said target, and applying radio frequency energy to said pedestal and said target.

3. The method of claim 1 including using a flow of argon gas to form said phase change material.

4. The method of claim 3 including using the self-ionization plasma to reduce the pressure of argon within a chalcogenide deposition apparatus.

5. The method of claim 1 including depositing the chalcogenide at a pressure less than 3 milliTorr.

6. The method of claim 5 including depositing the chalcogenide at a pressure less than 1 milliTorr.

7. The method of claim 6 including using an electrostatic chuck.

8. The method of claim 1 including forming a chalcogenide that does not change phase.

9. The method of claim 1 including forming an ovonic threshold switch.

10. The method of claim 1 including using said self-ionization plasma to reduce the amount of argon in the deposited chalcogenide.

11. A method comprising:
forming a chalcogenide layer for an ovonic threshold switch in a gas atmosphere having a pressure lower than 3 milliTorr.

12. The method of claim 11 including forming said chalcogenide layer at a pressure less than 1 milliTorr.

13. The method of claim 11 including forming a self-ionization plasma.

14. The method of claim 11 including using an electrostatic chuck.

15. The method of claim 11 including using a radio frequency source.

16. A method comprising:
depositing a chalcogenide layer for an ovonic threshold switch in a deposition chamber; and
using an electrostatic chuck to enable the pressure of argon to be reduced during the deposition of the chalcogenide layer.

17. The method of claim 16 including depositing the chalcogenide layer with an argon pressure less than 3 milliTorr.

18. The method of claim 17 including depositing the chalcogenide layer at a pressure less than 1 milliTorr.

19. The method of claim 16 including using a radio frequency plasma.

20. The method of claim 16 including using a deposition chamber with a ceramic clamp ring.

21. An apparatus comprising:
an argon gas source;
a wafer holder;
a deposition chamber coupled to said argon source, said chamber to deposit a chalcogenide on a wafer to form an ovonic threshold switch, said wafer held in said wafer holder at a gas pressure lower than 3 milliTorr.

22. The apparatus of claim 21 wherein said chamber maintains a pressure less than 1 milliTorr.

23. The apparatus of claim 21, said chamber to form a self-ionizaton plasma.

24. The apparatus of claim 21, said chamber including an electrostatic chuck.

25. The apparatus of claim 21, said chamber including a radio frequency source.

26. A system comprising
a processor;
a dynamic random access memory coupled to said processor; and
a chalcogenide memory coupled to said processor, said memory formed by a process involving the use of a self-ionization plasma.

27. The system of claim 26 wherein said memory includes an ovonic threshold switch.

28. The system of claim 27 wherein the ovonic threshold switch has a lower argon concentration than a switch made without using a self-ionization plasma.
